(19) United States
(12) Patent Application Publication
(10) Pub. No.: US 2015/0001467 A1
(43) Pub. Date: Jan. 1, 2015

(54) SEMICONDUCTOR DEVICE HAVING SUPERLATTICE THIN FILM LAMINATED BY SEMICONDUCTOR LAYER AND INSULATOR LAYER

(71) Applicant: Research & Business Foundation SUNGKYUNKWAN UNIVERSITY, Suwon-si (KR)

(72) Inventors: Hyung Koun CHO, Suwon-si (KR); Cheol Hyoun AHN, Suwon-si (KR)

(21) Appl. No.: 14/306,889

(22) Filed: Jun. 17, 2014

(30) Foreign Application Priority Data
Jul. 1, 2013 (KR) 10-2013-0076775

(51) Int. Cl. H01L 29/15; H01L 33/06; H01L 33/28; H01L 29/22

(52) U.S. Cl. CPC H01L 29/151; H01L 29/22; H01L 33/06; H01L 33/28
USPC 257/22

(57) ABSTRACT

Disclosed herein is a semiconductor device, including: a substrate; and a superlattice thin film formed on the substrate, wherein the superlattice thin film is configured such that insulator layers and semiconductor layers are alternately laminated on the substrate. The superlattice thin film is characterized in that, since it is formed by the lamination of a semiconductor layer and an insulator layer, the semiconductor layer and insulator layer constituting the superlattice thin film may be composed of a crystalline material, an amorphous material or a mixture thereof, and thus various kinds of materials for solving the mismatch in lattice constant between conventional superlattices made of different kinds of semiconductor materials can be used without limitations.

### CROSS-REFERENCE TO RELATED APPLICATION(S)

This application claims the benefit under 35 USC 119(a) of Korean Patent Application No. 10-2013-0076775 filed on Jul. 1, 2013, in the Korean Intellectual Property Office, the entire disclosure of which is incorporated herein by reference for all purposes.

### BACKGROUND OF THE INVENTION

1. Technical Field

The present invention relates to a semiconductor device including a superlattice thin film. More particularly, the present invention relates to a superlattice thin film formed by the lamination of a semiconductor layer and an insulator layer on a substrate.

### RELATED NATIONAL RESEARCH PROJECTS

The present invention is based on the results obtained from the research project (No. 2012-03849) “development of novel multi-component oxide thermoelectric material for applications of environmentally-friendly thermoelectric device”, conducted by Korea Science and Engineering Foundation, and the government research project (No. 2011-8520010050) “development of low-priced GIGS solar battery of a photoelectric conversion efficiency of 10%”, supported by Ministry of trade, industry and energy in Korea.

2. Description of the Related Art

Recently, research into improving the efficiency of a photoelectric device using a semiconductor device having a superlattice thin film formed by alternately laminating two or more kinds of semiconductor layers capable of overcoming the physical limitations of semiconductor materials has variously been conducted.

As a typical example, a photodiode uses a superlattice structure having a two-dimensional or three-dimensional quantum well structure as a light-emitting layer in order to obtain excellent luminous characteristics. A quantum well structure can more efficiently collect electric charges than a general diode structure, and thus high recombination of electrons and holes is induced, thereby improving luminous characteristics. Currently, a light emitting diode having a GaN-based superlattice structure is commercially widely used.

Further, recently, with the sudden rise in price of fossil fuels such as crude oil or the like and the increase in danger of international conflict in the Middle East, the fluctuation of oil prices in Korea has been ongoing, and with the exhaustion of fossil fuels, efforts to develop environmentally-friendly energy sources have been conducted. Environmentally-friendly energy sources may include various types of energy sources, such as solar energy, tidal energy, wind energy and the like. In order to improve the efficiency of such environmentally-friendly energy sources, research into raw materials and structures has actively been conducted.

Further, recently, a technology of producing energy using a thermoelectric material capable of converting waste heat generated from various devices and factories into electrical signals (Korean Patent Application No. 10-2010-0029518) has attracted considerable attention. Meanwhile, such a superlattice structure is used in improving the efficiency of a thermoelectric material because it has a repeatedly laminated structure that induces the scattering of phonons, thus lowering electrical conductivity of the thermoelectric material. Further, when a semiconductor material is formed to have a superlattice structure, a quantum effect can be expected, thus controlling the bandgap thereof. That is, the semiconductor material having such a superlattice structure can control the electrical characteristics to light, and therefore it is used for solar cells, photodiodes or the like.

However, since the existing semiconductor materials have a superlattice structure laminated by different kinds of semiconductors (semiconductor-semiconductor), a single-crystal super lattice must be realized in order to control the lattice constant between semiconductors and the defects of semiconductors.

For this reason, there is a problem in that a high-temperature process is necessary to obtain a high-quality single-crystal superlattice. Further, there is a problem in that the kinds of semiconductor materials having lattice constants matching with each other are restricted, and thus they can be limitedly used. Moreover, there is a problem in that, in order to obtain an epitaxial thin film, a substrate, the lattice constant of which does not greatly match with that of the thin film, is required, and single-crystal substrates having a structure the same as or similar to each other must be used, and thus there are economical and technical limitations in applying these semiconductor material to various kinds of devices.

Meanwhile, since an amorphous silicon transistor, generally used as a device for a display backplane, has only a mobility of 1 cm²/Vs, novel materials having high mobility are required in order to realize large-area and high-resolution displays.

A method of crystallizing amorphous silicon is used to increase mobility, but this method has a problem of requiring a high-temperature process. Since most of display panels use glass, their usable process temperature is not high. Further, since a lower process temperature has lately been required to realize transparent or flexible next-generation displays, the high process temperature is not suitable therefor.

It was reported in the paper (Nature 432, 488-482, 2004) that a transistor device including an amorphous IGZO oxide semiconductor as an active layer has a mobility of 10 cm²/VS or more. Thereafter, transistor devices including an amorphous oxide semiconductor and having a mobility of 10 cm²/VS or more have been reported. However, these transistor devices are problematic in that threshold voltage is unstable under various conditions.

Further, it is reported that a comparative stable device also exhibits a mobility of 10 cm²/Vs, thus reaching technical limitation.

Meanwhile, it was reported in the paper (Science, Vol. 300, p. 1269, 2003) that, when an IGZO oxide semiconductor having a monocrystalline superlattice structure was used as a channel layer, a high mobility of 80 cm²/Vs was realized, and that, even when a ZnO/MgZnO-based superlattice structure or GaN-based superlattice structure was used, excellent mobility was realized. However, such superlattice structures require the growth of high-quality single crystals, and thus the use thereof was restricted.

### SUMMARY OF THE INVENTION

Accordingly, the present invention has been devised to solve the above-mentioned problems, and provides a semiconductor device including a superlattice thin film formed by the lamination of a semiconductor layer and an insulator layer. The semiconductor device is characterized as follows.

First, since the superlattice thin film is formed by the lamination of a semiconductor layer and an insulator layer, the semiconductor layer and insulator layer constituting the superlattice thin film may be composed of a crystalline material, an amorphous material or a mixture thereof, and thus various kinds of materials for solving the mismatch in lattice constant between conventional superlattices made of different kinds of semiconductor materials can be used without limitations.

Second, since the optical and electrical characteristics of the superlattice thin film formed by the lamination of the semiconductor layer and the insulator layer depend on the characteristics of the semiconductor layer used as an active layer, this superlattice thin film can be applied to various kinds of devices.

Third, the superlattice thin film can be used over a wide temperature range because its crystallinity and growth temperature are not greatly restricted.

The objects of the present invention are not limited to the above-mentioned objects, and the not-mentioned other objects thereof will be clearly understood to those skilled in the art by the following descriptions.

In order to accomplish the above object, an aspect of the present invention provides a semiconductor device, including: a substrate; and a superlattice thin film formed on the substrate, wherein the superlattice thin film is configured such that insulator layers and semiconductor layers are alternately laminated on the substrate.

Here, the insulator layer may be made of Al₂O₃, and the semiconductor layer may be made of ZnO.

The superlattice thin film may be formed by any one of sputtering, molecular beam epitaxy (MBE), evaporation, chemical vapor deposition (CVD), atomic layer deposition (ALD) and a sol-gel process.

The semiconductor layer of the superlattice thin film may be an active layer.

In the case of bands of the superlattice thin film, the conduction band of the semiconductor layer may be smaller than that of the insulator layer, and may be larger than the valence band of the insulator layer.

In the case of bands of the superlattice thin film, the conduction band of the semiconductor layer may be smaller than that of the insulator layer, and may be larger than the valence band of the insulator layer.

In the case of bands of the superlattice thin film, the conduction band and valence band of the semiconductor layer may be larger than those of the insulator layer.

When electric current flows in the vertical direction of the superlattice thin film, the insulator layer may have a thickness (t1) of 0<t≦10 nm, and the semiconductor layer (t2) may have a thickness of 0<t2≦100 nm. The amount of electric current may be controlled by setting the thickness (t2) of the semiconductor layer constant and adjusting the thickness (t1) of the insulator layer.

When electric current flows in the lateral direction of the superlattice thin film, the insulator layer may have a thickness (t1) of 10<t1<100 nm, and the semiconductor layer (t2) may have a thickness of 0<t2≦100 nm. The amount of electric current may be controlled by setting the thickness (t1) of the insulator layer constant and adjusting the thickness (t2) of the semiconductor layer.

When electric current flows in both the vertical direction and lateral direction of the superlattice thin film, the insulator layer may have a thickness (t1) of 0<t1≦10 nm, and the semiconductor layer (t2) may have a thickness of 0<t2≦100 nm. The amount of electric current may be controlled by setting the thickness (t2) of the semiconductor layer constant and adjusting the thickness (t1) of the insulator layer or by adjusting both the thickness (t1) of the insulator layer and the thickness (t2) of the semiconductor layer.

### BRIEF DESCRIPTION OF THE DRAWINGS

The above and other objects, features and advantages of the present invention will be more clearly understood from the following detailed description taken in conjunction with the accompanying drawings, in which:

FIGS. 1 and 2 are schematic sectional views showing a semiconductor device including a superlattice thin film according to an embodiment of the present invention.

FIG. 3 is a sectional view showing the superlattice thin film composed of semiconductor layers and insulator layers according to the present invention.

FIG. 4 is a transmission electron microscope (TEM) image of the superlattice thin film according to the present invention.

FIGS. 5 to 7 show the band structures capable of being formed by the superlattice thin film according to the present invention.

FIG. 8 is a schematic view explaining the structural control of the layers constituting the superlattice thin film according to the direction of electric current.

FIG. 9 is a graph showing the current-voltage characteristics of a field-effect transistor including the superlattice thin film of FIG. 1 as an active layer.

FIG. 10 is a graph showing the current-voltage characteristics of the semiconductor device of FIG. 2 according to the thickness of the semiconductor layer, wherein current density is measured in a direction toward the arrow b of FIG. 8.

FIG. 11 is a schematic sectional view showing a semiconductor device including a superlattice thin film according to another embodiment of the present invention.

FIGS. 12 and 13 are graphs showing the current-voltage characteristics of the semiconductor device of FIG. 11 according to the thickness of the semiconductor layer and the thickness of the insulator layer, respectively, wherein current density is measured in a direction toward the arrow a of FIG. 8.

FIGS. 14 and 15 are graphs showing the current and thermal conductivity of the superlattice thin film with respect to temperature, which were measured for applying the superlattice thin film to a thermoelectric device.

FIG. 16 is a graph showing the results of analyzing the photoluminescence of the superlattice thin film composed of the semiconductor layer (ZnO layer) having a thickness of 100 nm and the insulator layer.

### DESCRIPTION OF THE PREFERRED EMBODIMENTS

Hereinafter, preferred embodiments of the present invention will be described in detail with reference to the attached drawings.

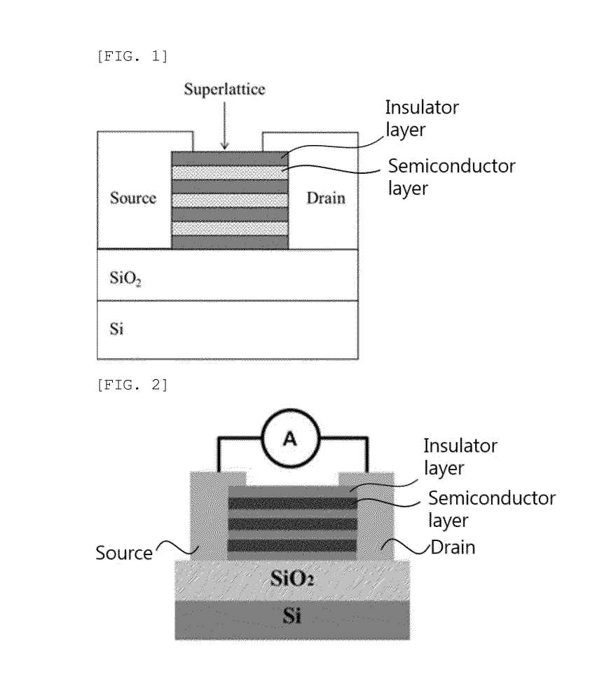

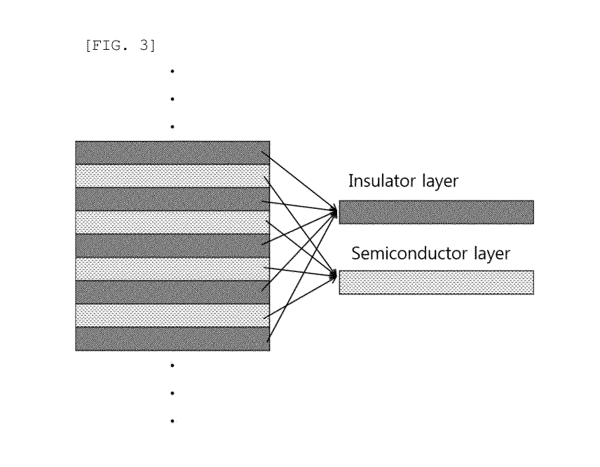

FIGS. 1 and 2 are schematic sectional views showing a semiconductor device including a superlattice thin film according to an embodiment of the present invention.

The present invention pertains to a semiconductor device including a superlattice thin film formed on a substrate.

The superlattice thin film according to the present invention may be formed by alternately laminating insulator layers and semiconductor layers on a substrate.

That is, the superlattice thin film is configured such that semiconductor layers and insulator layers are laminated periodically and alternately. Further, in the superlattice thin film, the semiconductor layer and insulator layer may be made of a crystalline material, an amorphous material or a mixture thereof.

The superlattice thin film composed of the semiconductor layer and the insulator layer according to the present invention can use both a substrate for high temperature and a substrate for low temperature generally used in photoelectric devices because it is not greatly limited in crystallinity. For example, the substrate may be selected from among a glass substrate, a metal foil substrate, a metal substrate, a low-molecular or high-molecular plastic substrate, an amorphous oxide/nitride substrate, a transparent ITO substrate, and a crystalline silicon substrate.

The superlattice thin film according to the present invention may be formed by any one of: physical growth methods such as sputtering, molecular beam epitaxy (MBE), evaporation and the like; chemical growth methods, such as chemical vapor deposition (CVD), atomic layer deposition (ALD) and the like; and solution-based growth methods such as a sol-gel process and the like.

The active layer in the superlattice thin film of the present invention may be the semiconductor layer. The active layer in the superlattice thin film functions as follows.

First, the active layer confers electrical characteristics to the superlattice thin film composed of the semiconductor layer and the insulator layer, and can control the electrical characteristics thereof depending on the thickness of the semiconductor layer.

Second, the active layer confers optical characteristics to the superlattice thin film, and can control the wavelength of receivable and emittable light depending on the bandgap of the semiconductor layer.

Meanwhile, the insulator layer in the superlattice thin film may also be used as an active layer, but, in this case, there are the following disadvantages.

First, the movement of electric charges is not easy because the density of electric charges in the insulator layer is low and the electric charged must be moved by a hopping mechanism.

Second, in the application of the superlattice thin film into optical devices such as photodiodes, it is difficult to use the insulator layer as an active layer because the recombination and light-receiving of electrons and holes in the insulator layer are easy due to the relative bandgap difference therebetween.

Third, electric current does not easily flow because an electrode making ohmic contact with the insulator layer cannot be formed in the configuration of a device.

In contrast, when the semiconductor layer is used as an active layer, there are following advantages.

First, the recombination of electrons and holes in the semiconductor layer can be highly induced by the relative bandgap, and the light-emitting and light-receiving wavelengths can be easily controlled by the bandgap of the semiconductor layer.

Second, since the semiconductor layer has high electrical conductivity, high electric current can be induced from a semiconductor device, thus realizing a useful semiconductor device.

Third, a metal electrode capable of making ohmic contact with the semiconductor layer can be formed, thus allowing electric current to flow easily.

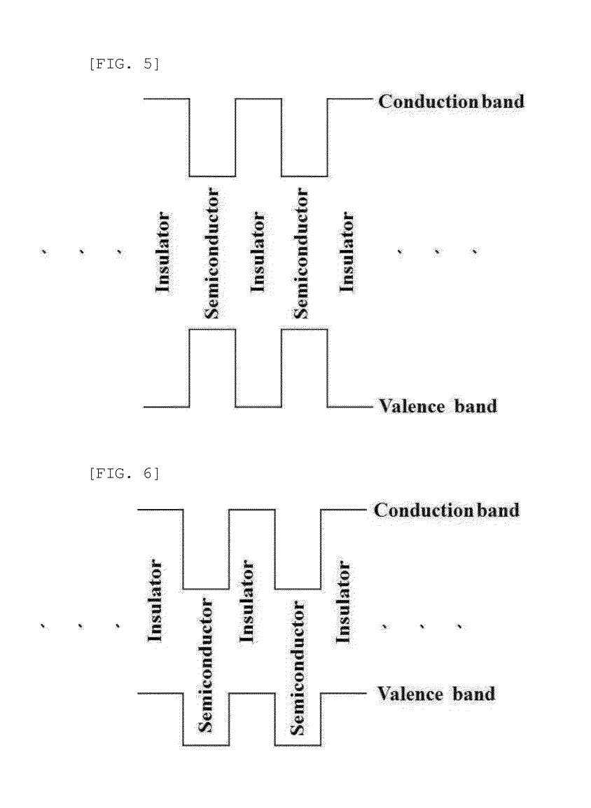

FIGS. 5 to 7 show three types of band structures of the superlattice thin film composed of semiconductor layers and insulator layers.

First, as shown in FIG. 5, the conduction band of the semiconductor layer may be smaller than that of the insulator layer, and may be larger than the valence band of the insulator layer.

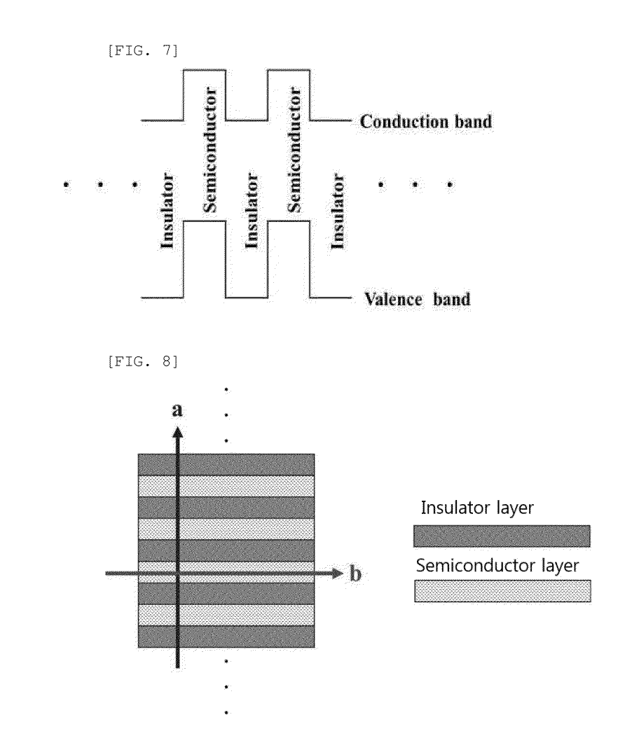

Second, as shown in FIG. 6, the conduction band of the semiconductor layer may be smaller than that of the insulator layer, and may be smaller than the valence band of the insulator layer.

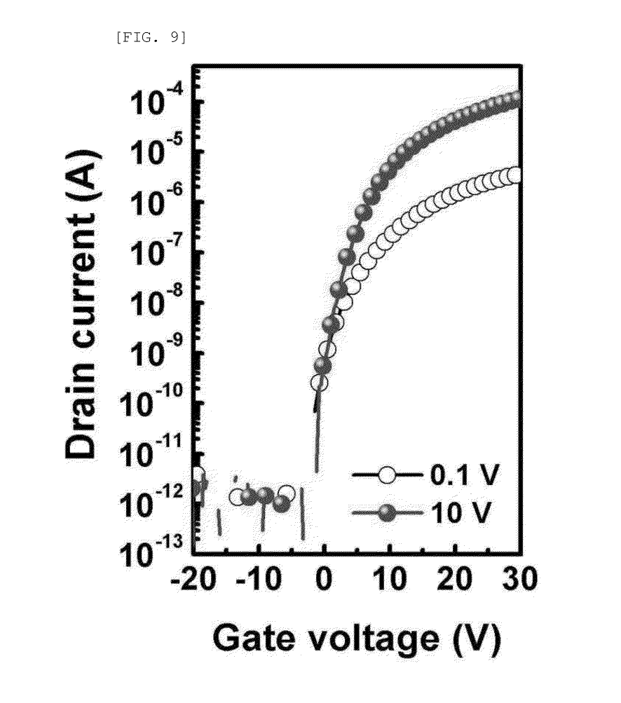

Third, as shown in FIG. 7, the conduction band and valence band of the semiconductor layer may be larger than those of the insulator layer.

The band structures may be selected depending on the control of electric and optical characteristics of the superlattice thin film composed of semiconductor layers and insulator layers.

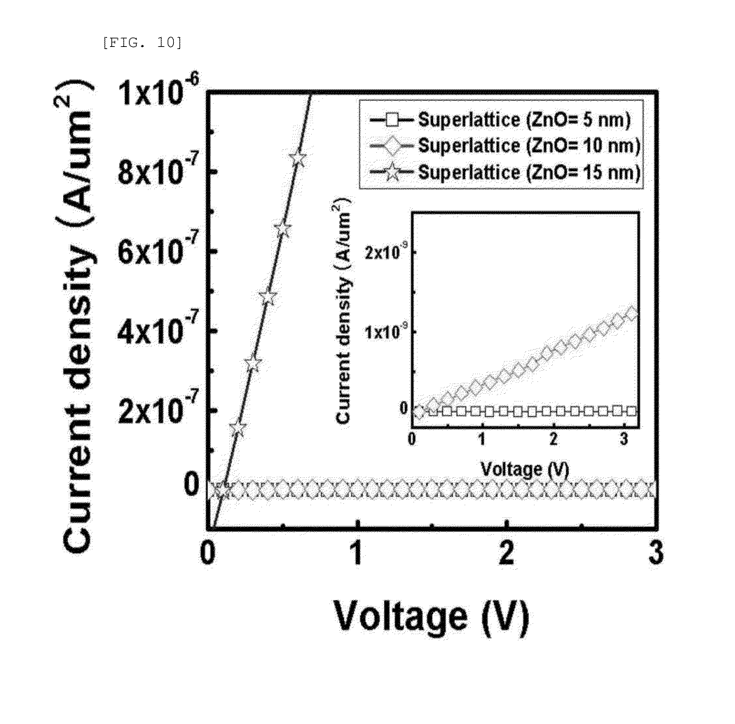

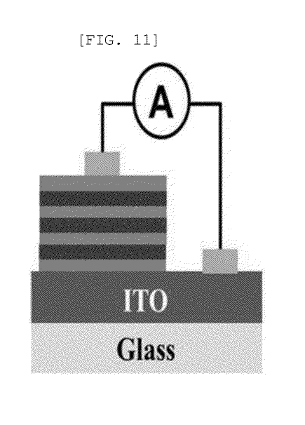

FIG. 8 explains the structural control of the layers constituting the superlattice structure according to the direction of electric current.

When electric current flows in the vertical direction (a) of the superlattice thin film, that is, in the direction of the arrow a in FIG. 8, in order for electrons to easily flow, the insulator layer may have a thickness (t1) of 0<t1≦10 nm.

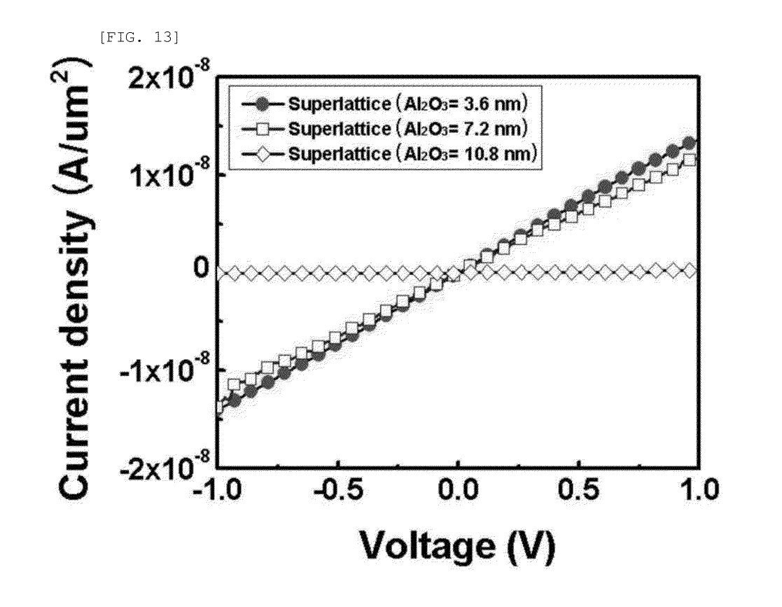

Electric charges in the semiconductor layer flow into the insulator layer through direct tunneling or field-emission tunneling (Fowler-Nordheim tunneling). However, with the increase in thickness of the insulator layer, the flow of electric current through direct tunneling or field-emission tunneling (Fowler-Nordheim tunneling) becomes more difficult. Referring to FIG. 13, it can be ascertained that the density of electric current is remarkably lowered when the thickness of the insulator layer is more than 10 nm.

When the thickness of the insulator layer is more than 10 nm, the electric charges in the semiconductor layer act as a factor inhibiting the flow of electric current because the tunneling thereof via the insulator layer is restricted. Therefore, when the thickness of the insulator layer is more than 10 nm, the flow of electric current in the vertical direction (a) of the superlattice thin film is restricted, and thus this insulator layer is suitable for a device requiring the flow of electric current in the lateral direction (b) of the superlattice thin film.

When electric current flows in the lateral direction (b) of the superlattice thin film, that is, in the direction of the arrow b in FIG. 8, the semiconductor layer may have a thickness (t2) of 0<t2≦100 nm. The amount of electric current may be controlled by adjusting the thickness (t2) of the semiconductor layer.

The electric current flow of the semiconductor layer in the lateral direction (b) of the superlattice thin film can be controlled depending on the thickness of the semiconductor layer. The state density function of electric charges in the material used in the semiconductor layer at the Fermi level due to a quantum confinement effect may be increased with the decrease in thickness of the semiconductor layer. For this reason, the conductivity of the semiconductor layer in the lateral direction (b) of the superlattice thin film gradually decreases. In contrast, when the thickness thereof is larger than critical thickness exhibiting the quantum confinement effect, the conductivity of the semiconductor layer gradually increases. For this reason, the amount of electric current in the lateral direction (b) of the superlattice thin film may be controlled depending on the thickness of the semiconductor layer. However, as the thickness of the semiconductor layer increases, the semiconductor layer in the superlattice thin film exhibits general bulk characteristics, not a nanostructure effect (quantum effect). Therefore, it is preferred that the thickness (t2) of the semiconductor layer be present in the range of 0<t2≦100 nm.

The thickness range of the semiconductor layer, which can expect the generation of a quantum effect and the control of a bandgap, is 100 nm or less. When the thickness thereof is more than 100 nm, the bulk characteristics are dominantly exhibited compared to the quantum effect.

When electric current flows in both the vertical direction (a) and lateral direction (b) of the superlattice thin film, the insulator layer may have a thickness (t1) of 0<t1≦10 nm, and the semiconductor layer (t2) may have a thickness of 0<t2≦100 nm. Here, the amount of electric current may be controlled by adjusting both the thickness (t1) of the insulator layer and the thickness (t2) of the semiconductor layer.

According to an embodiment of the present invention, the insulator layer may be made of Al₂O₃, and the semiconductor layer may be made of ZnO.

According to a first embodiment of the present invention, the amount of electric current may be controlled by setting the thickness (t1) of the insulator layer constant and adjusting the thickness (t2) of the semiconductor layer. In this embodiment, the flow of electric current in the lateral direction (b) of the superlattice thin film is controlled.

According to a second embodiment of the present invention, the amount of electric current may be controlled by setting the thickness (t2) of the semiconductor layer constant and adjusting the thickness (t1) of the insulator layer. In this embodiment, the flow of electric current in the vertical direction (a) of the superlattice thin film is controlled. However, when the thickness (t1) of the insulator layer is excessively large, electric current may not flow in the vertical direction (a) of the superlattice thin film, and thus the thickness thereof is adjusted.

According to a third embodiment of the present invention, the amount of electric current may be controlled by adjusting both the thickness (t1) of the insulator layer and the thickness (t2) of the semiconductor layer. In this embodiment, the flow of electric current in the both directions (a) and (b) of the superlattice thin film is controlled. However, the thickness range thereof is changed depending on the use thereof.

The conductivity of the superlattice thin film is controlled by the thickness of the semiconductor layer because the conductivity thereof is conferred by the semiconductor layer, and the insulator layer serves to control the ease of electric current flow. For reference, the insulator layer is a layer for providing a quantum effect to the semiconductor layer, that is, a layer for restricting bands.

Briefly explaining, in the case of a semiconductor device controlling electric current in a vertical direction or both vertical and lateral directions, the thickness (t1) of the insulator layer may be set to 0<t1≦10 nm, and the thickness (t2) of the semiconductor layer may be set to 0<t2≦100 nm.

In the case of a semiconductor device controlling electric current in a vertical direction, the thickness (t1) of the insulator layer may be set to 10<t1≦<100 nm, and the thickness (t2) of the semiconductor layer may be set to 0<t2≦100 nm.

The electric current in the vertical direction may be controlled depending on the thickness (t1) of the insulator layer, and the electric current in the lateral direction may be controlled depending on the thickness (t2) of the semiconductor layer. However, it can be seen that the electric current in the vertical direction is slowly increased depending on the thickness (t2) of the semiconductor layer.

As described above, the present invention is characterized in that the amount of electric current can be controlled according to the use thereof depending on the thickness of the semiconductor layer.

The superlattice thin film can be used as an active layer of a field-effect transistor, and can also be used as an active layer of thermoelectric device and electric and optical devices.

Hereinafter, the present invention will be described in more detail with reference to the following Examples.

### Example 1

Example 1 pertains to the application of a field-effect transistor, and to a device for utilizing electric current in both directions.

A superlattice thin film composed of a semiconductor layer and an insulator layer was formed by growing the semiconductor layer and the insulator layer using atomic layer deposition (ALD).

ZnO (semiconductor), as a semiconducting material, and Al₂O₃, as an insulating material, were periodically and alternately grown on a SiO₂/Si substrate having an area of 2×2 cm², so as to form the superlattice thin film.

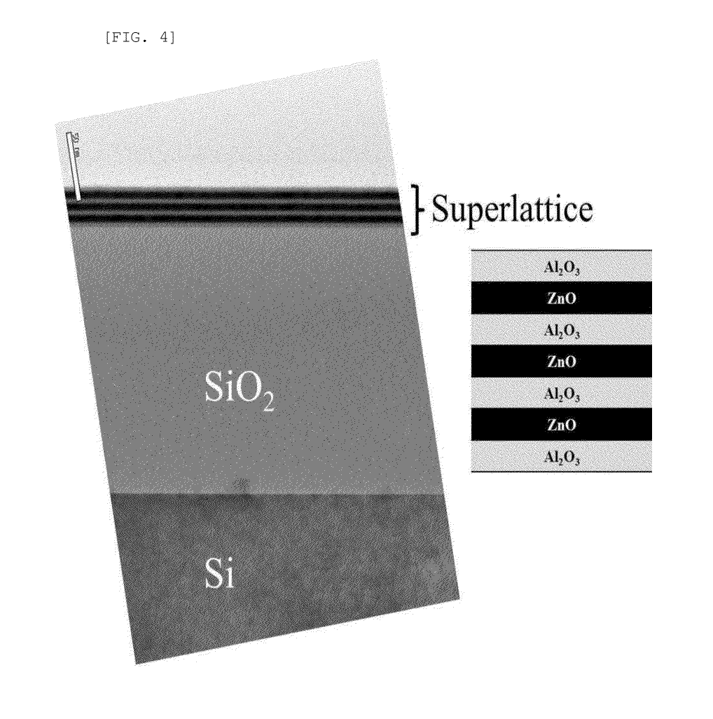

Diethyl zinc (DEZn) and trimethyl aluminum (TMAl) were used as Zn precursor and Al precursor, respectively. Oxygen was grown using H₂O. FIG. 4 shows a transmission electron microscope (TEM) image of the superlattice thin film formed by atomic layer deposition (ALD). Then, the superlattice thin film composed of the grown semiconductor layer (5 nm) and the grown insulator layer (3.6 nm) and grown to a thickness of about 30 nm was patterned in order to use this superlattice thin film as an active layer of a field-effect transistor. Thereafter, source/drain electrodes were formed on the patterned superlattice thin film using an electron beam evaporator. FIG. 1 shows a field-effect transistor including this superlattice thin film as an active layer. FIG. 9 shows the results of evaluating the current-voltage characteristics of the field-effect transistor. The field-effect mobility of the transistor was very high (27.8 cm²/Vs).

### Example 2

Example 2 pertains to the measurement of electric current change of a superlattice thin film composed of a semiconductor layer and an insulator layer according to the thicknesses of the semiconductor layer and the insulator layer.

In order to analyze the change in electric current of the superlattice thin film composed of the semiconductor layer and the insulator layer according to the thicknesses of the semiconductor layer and the insulator layer, the electrical characteristics of the superlattice thin film according to the thicknesses of the semiconductor layer and the insulator layer were evaluated by atomic layer deposition (ALD).

ZnO (semiconductor), as a semiconducting material, and Al₂O₃, as an insulating material, were periodically and alternately grown on a SiO₂/Si substrate having an area of 2×2 cm², so as to form the superlattice thin film. Then, the superlattice thin film composed of the grown semiconductor layer and the grown insulator layer and grown on the SiO₂/Si substrate was patterned in order to ascertain the influence of electric current in the lateral direction (b) of FIG. 8. Thereafter, source/drain electrodes were formed at both ends of the patterned superlattice thin film using an electron beam evaporator, and then the analysis thereof was performed.

FIGS. 2 and 10 show the results of evaluating the current-voltage characteristics of the superlattice thin film according to the thickness of the semiconductor layer. As shown in FIG. 10, it can be ascertained that current density increases with the increase in thickness of the semiconductor layer. From the result, it can be seen that the electric current (lateral current) in the lateral direction (b) of the superlattice thin film can be improved by increasing the thickness of a conductive layer.

Meanwhile, in order to ascertain the influence of electric current in the vertical direction (a) of FIG. 8, the superlattice thin film grown on an ITO/glass substrate was patterned, and then an upper electrode was formed using an electron beam evaporator, and then the analysis thereof was performed.

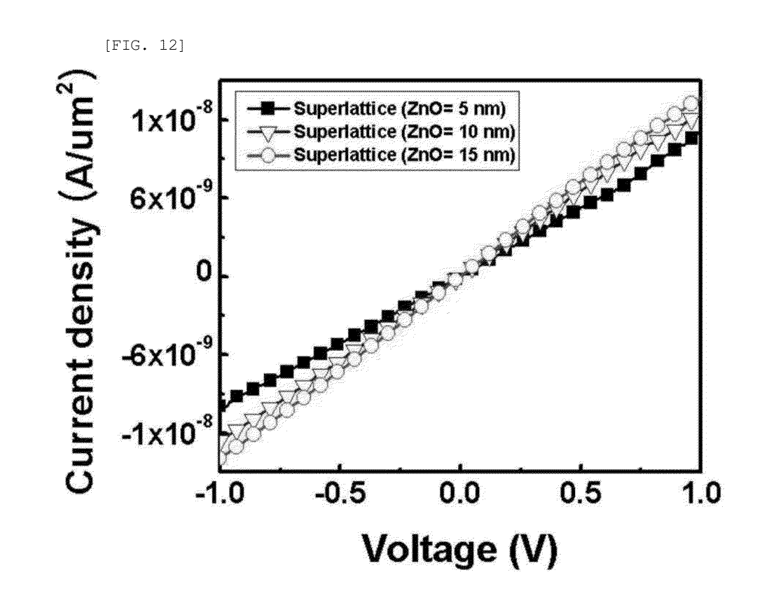

FIGS. 12 and 13 shows the results of evaluating the current-voltage characteristics of the superlattice thin film according to the thickness of the semiconductor layer and the thickness of the insulator layer, respectively. From FIGS. 12 and 13, it can be ascertained that the change in electric current according to the thickness of the semiconductor layer is not great, but the amount of electric current decreases with the increase in thickness of the insulator layer.

That is, it can ascertained that the amount of electric current flowing in the vertical direction (a) of the superlattice thin film of FIG. 8 decreases with the increase in thickness of the insulator layer because electron tunneling is difficult.

Consequently, it can be ascertained that the amount of electric current can be controlled by the thicknesses of the semiconductor layer and the insulator layer.

### Example 3

Example 3 pertains to the application of a thermoelectric device.

In order to ascertain the applicability of a superlattice thin film composed of a semiconductor layer and an insulator layer into a thermoelectric device, the semiconductor layer and the insulator layer were grown on a sapphire substrate having an area of 3×3 cm² by atomic layer deposition (ALD) to form the superlattice thin film, and then the characteristics thereof were evaluated.

ZnO (semiconductor), as a semiconducting material, was grown into a semiconductor layer having a thickness of 5 nm, and Al₂O₃, as an insulating material, was grown into an insulator layer having a thickness of 3.6 nm, and then each of the layers was periodically grown to form a superlattice thin film having a total thickness of 200 nm.

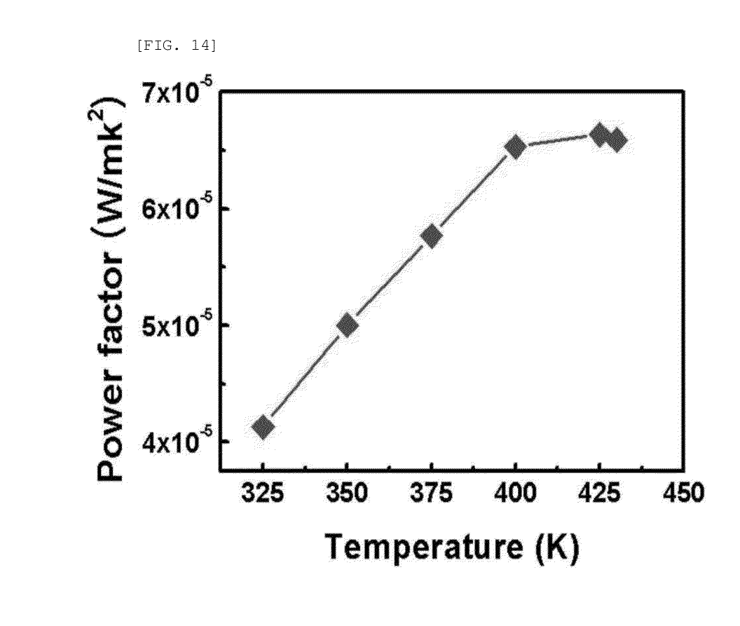

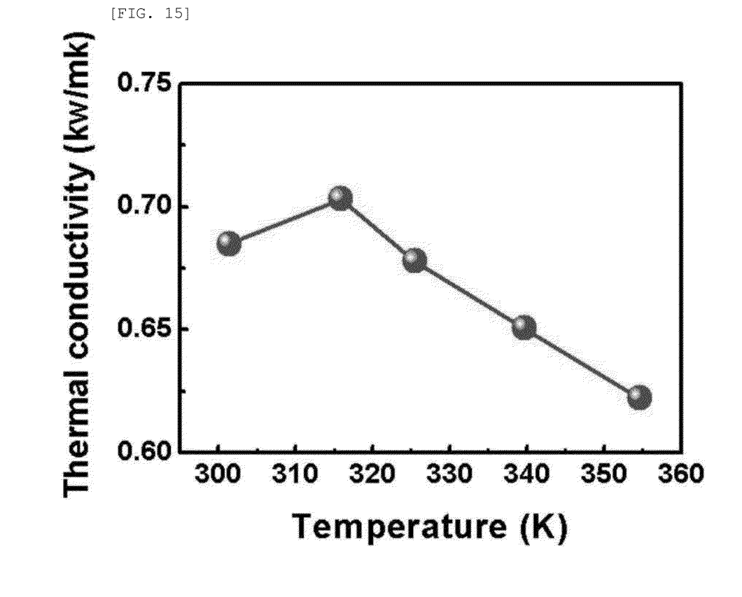

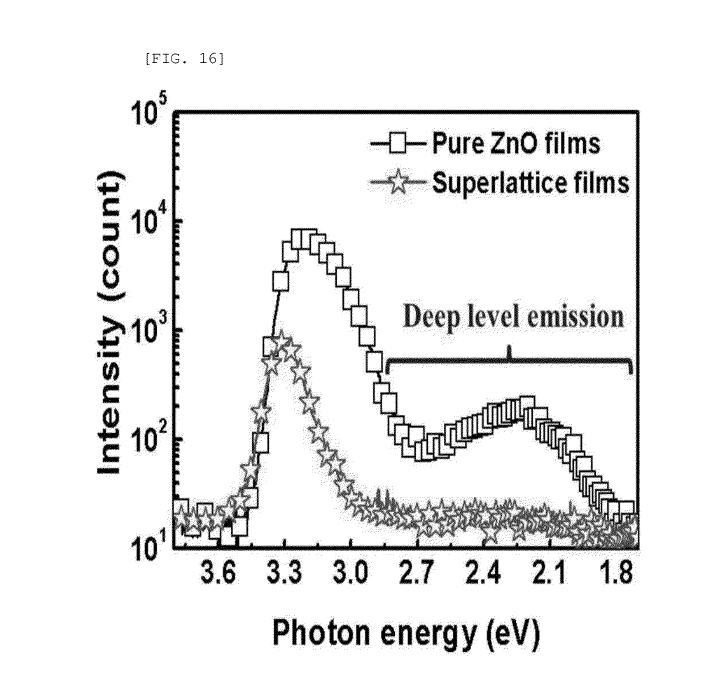

FIGS. 14 and 15 show the results of analyzing the Seebeck coefficient, power factor and thermal conductivity of the superlattice thin film. From FIGS. 14 and 15, it can be ascertained that the thermal conductivity of the superlattice thin film was remarkably deteriorated because the electrons and phonons in a conductive layer were scattered by an insulating layer, and that the power factor of the superlattice thin film at 425K is 6.65×10⁻⁵ W/mK².

### Example 4

Example 4 pertains to the analysis of optical characteristics.

In order to ascertain the applicability of a superlattice thin film composed of a semiconductor layer and an insulator layer into a thermoelectric device, the applicability thereof was evaluated by photoluminescence analysis.

The semiconductor layer and the insulator layer were grown on a sapphire substrate or SiO₂/Si substrate having an area of 3×3 cm² by atomic layer deposition (ALD) to form the superlattice thin film, and then the characteristics thereof were evaluated.

ZnO (semiconductor), as a semiconducting material, was grown into a semiconductor layer having a thickness of 5 nm, and Al₂O₃, as an insulating material, was grown into an insulator layer having a thickness of 3.6 nm, and then each of the layers was periodically grown to form a superlattice thin film having a total thickness of 99.7 nm.

Generally, a ZnO conductive layer has high exciton binding energy, and thus research into applying this ZnO conductive layer to an optical device, such as light-emitting diode, laser or the like, has been widely conducted.

However, the ZnO conductive layer has a bandgap corresponding to ultraviolet due to its defects such as oxygen depletion, but is known to emit and absorb light in the visible light range.

FIG. 16 shows the results of analyzing the photoluminescence of a pure ZnO film having a thickness of 100 nm and a super lattice thin film composed of a semiconductor (ZnO) layer and an insulator (Al₂O₃) layer.

From FIG. 16, it can be ascertained that the emission peak of the superlattice thin film in the visible light range was shifted into short-wavelength energy band due to a quantum effect, and that the deep-level emission of the superlattice thin film in the visible light range was not observed due to the defect in energy level.

As described above, the semiconductor device including the superlattice thin film formed by the lamination of a semiconductor layer and an insulator layer according to the present invention is advantageous as follows.

First, in the formation of a semiconductor device including a superlattice thin film composed of a semiconductor layer and an insulator layer, the semiconductor layer is used as an active layer, thus realizing a semiconductor device having higher current density.

Second, in the semiconductor device including a superlattice thin film composed of a semiconductor layer and an insulator layer, the wavelengths of light-emitting and light-receiving devices can be controlled depending on the bandgap and electrical characteristics of a material used in the semiconductor layer.

Third, since the crystallinity of the semiconductor layer and insulator layer constituting the superlattice thin film of the present invention is not restricted, a semiconductor device, which can be used in a low-temperature process essential for the application of flexible devices, can be produced, and can also be used in a high-temperature process.

Fourth, the electric current of the superlattice thin film of the present invention in the vertical direction thereof can be controlled by adjusting the thickness of the insulator layer, and the electric current thereof in the vertical direction thereof can be controlled by adjusting the thickness of the semiconductor layer, thus controlling the flow of electric current according to the use thereof.

The effects of the present invention are not limited to the above-mentioned effects, and the not-mentioned other effects thereof will be clearly understood to those skilled in the art by the following descriptions.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor device, comprising:
a substrate; and
a superlattice thin film formed on the substrate,
wherein the superlattice thin film is configured such that insulator layers and semiconductor layers are alternately laminated on the substrate.

2. The semiconductor device of claim 1, wherein the insulator layer is made of Al₂O₃, and the semiconductor layer is made of ZnO.

3. The semiconductor device of claim 1, wherein the superlattice thin film is formed by any one of sputtering, molecular beam epitaxy (MBE), evaporation, chemical vapor deposition (CVD), atomic layer deposition (ALD) and a sol-gel process.

4. The semiconductor device of claim 1, wherein the semiconductor layer of the superlattice thin film is an active layer.

5. The semiconductor device of claim 1, wherein, in the case of bands of the superlattice thin film, the conduction band of the semiconductor layer is smaller than that of the insulator layer, and is larger than the valence band of the insulator layer.

6. The semiconductor device of claim 1, wherein, in the case of bands of the superlattice thin film, the conduction band of the semiconductor layer is smaller than that of the insulator layer, and is smaller than the valence band of the insulator layer.

7. The semiconductor device of claim 1, wherein, in the case of bands of the superlattice thin film, the conduction band and valence band of the semiconductor layer are larger than those of the insulator layer.

8. The semiconductor device of claim 1, wherein, when electric current flows in a vertical direction of the superlattice thin film, the insulator layer has a thickness (t1) of 0<t1≦10 nm, and the semiconductor layer (t2) has a thickness of 0<t2≦100 nm.

9. The semiconductor device of claim 8, wherein the amount of electric current is controlled by setting the thickness (t2) of the semiconductor layer constant and adjusting the thickness (t1) of the insulator layer.

10. The semiconductor device of claim 1, wherein, when electric current flows in the lateral direction of the superlattice thin film, the insulator layer has a thickness (t1) of 10<t1≦<100 nm, and the semiconductor layer (t2) has a thickness of 0<t2≦100 nm.

11. The semiconductor device of claim 10, wherein the amount of electric current is controlled by setting the thickness (t1) of the insulator layer constant and adjusting the thickness (t2) of the semiconductor layer.

12. The semiconductor device of claim 1, wherein, when electric current flows in both the vertical direction and lateral direction of the superlattice thin film, the insulator layer has a thickness (t1) of 0<t1≦10 nm, and the semiconductor layer (t2) has a thickness of 0<t2≦100 nm.

13. The semiconductor device of claim 12, wherein the amount of electric current is controlled by setting the thickness (t2) of the semiconductor layer constant and adjusting the thickness (t1) of the insulator layer.

14. The semiconductor device of claim 12, wherein the amount of electric current is controlled by adjusting both the thickness (t1) of the insulator layer and the thickness (t2) of the semiconductor layer.
